(19) United States
(12) Patent Application Publication
(10) Pub. No.: US 2015/0061080 A1
(43) Pub. Date: Mar. 5, 2015

(54) GUARD RING STRUCTURE OF SEMICONDUCTOR APPARATUS

(71) Applicant: SK hynix Inc., Icheon-si (KR)

(72) Inventor: Sang Bum LEE, Icheon-si Gyeonggi-do (KR)

(73) Assignee: SK hynix Inc., Icheon-si (KR)

(21) Appl. No.: 14/100,541

(22) Filed: Dec. 9, 2013

(30) Foreign Application Priority Data
Aug. 30, 2013 (KR) 10-2013-0103843

(51) Int. Cl. H01L 23/00

(52) U.S. Cl. CPC H01L 23/562
USPC 257/620

(57) ABSTRACT

A guard ring structure of a semiconductor apparatus includes a base wiring layer located above a semiconductor substrate, a first guard ring configured as a wiring stacked structure of two or more layers adjacent to the side of the device forming region above the base wiring layer, and a second guard ring configured to be stacked with the same number of layers as the first guard ring and separated from the first guard ring, the second guard ring formed adjacent to the side of a scribe lane above the base wiring layer.

### CROSS-REFERENCES TO RELATED APPLICATION

The present application claims priority under 35 U.S.C. §119(a) to Korean application number 10-2013-0103843, filed on Aug. 30, 2013, in the Korean Intellectual Property Office, which is incorporated herein by reference in its entirety.

### BACKGROUND

1. Technical Field

Various embodiments relate to a semiconductor integrated circuit, and more particularly, to a guard ring structure of a semiconductor apparatus.

2. Related Art

In a process of manufacturing a semiconductor apparatus, after a plurality of devices are formed above one semiconductor wafer, the semiconductor wafer is cut along a dicing line (or scribe lane) and separated into individual chips.

In other words, the scribe lane region is a region that is used to separate a semiconductor wafer into individual chips, and the interfaces of a large number of interlayer insulating layers that are stacked in the process of forming the device are exposed on the sidewall of the scribe lane region. The interfaces serve as penetration paths for water. As such, this may cause problems regarding reliability and yield degradation such as malfunction and breaking of the semiconductor chip. Furthermore, stress applied during the dicing process may cause cracks in the interlayer insulating layer, and the cracks may also serve as penetration paths for water.

Therefore, the structure surrounding the chip, that is, a guard ring, is formed outside the chip, and thereby penetration of water or propagation of the cracks may be prevented.

FIG. 1 is a conceptual plan view of a general semiconductor wafer.

A plurality of device forming regions 12A, 12B, 12C, and 12D are present on a wafer 10, and guard ring regions 14A, 14B, 14C, and 14D are present at the edges of the device forming regions 12A, 12B, 12C, and 12D, respectively. Separation of the individual chips is performed by dicing a scribe lane region 16.

The guard ring structures formed together in the formation of the wiring layers to the device forming regions 12A, 12B, 12C, and 12D are formed in the guard ring regions 14A, 14B, 14C, and 14D, respectively.

A guard ring is introduced to isolate the chip from the exterior, and thereby stress applied to the chip during the packaging process such as dicing or chipping can be minimized.

FIG. 2 is a diagram illustrating a general guard ring structure.

A semiconductor substrate 21 having an active region 23 defined by an isolation layer 22 is provided.

A guard ring structure 20 includes a first wiring layer 24, a second wiring layer 25, and a third wiring layer 26. The first wiring layer 24 is electrically coupled to the active region 23 via a first contact 24C, and the second wiring layer 25 is electrically coupled to the first wiring layer 24 via a second contact 25C. The third wiring layer 26 is electrically coupled to the second wiring layer 25 via a third contact 26C.

The first wiring layer 24 and the third wiring layer 26 are to formed to extend from the boundary of the device forming region to the boundary of the scribe lane SL. In other words, it can be seen that the third wiring layer 26 has a structure which is extended and formed in a single line.

In order to separate the chips having such a guard ring structure into individual chips, in a dicing process through the scribe lane region, a load is exerted on the guard ring structure, in particular, the largest load is exerted on the third wiring layer 26 that is the uppermost layer. Therefore, the third wiring layer 26 may collapse in the dicing process, and thus the interfaces of the device forming region may be exposed.

Furthermore, application of the stress caused during the dicing process increases when the layer is positioned in a higher part. Accordingly, since a height difference between the third wiring layer 26 and the second wiring layer 25 is greater, damage that is generated due to the load exerted on the third wiring layer 26 formed in a single line may be more severely propagated.

### SUMMARY

In an embodiment of the present technology, a guard ring structure of a semiconductor apparatus is formed at an edge of a device forming region, the guard ring structure may include: a base wiring layer located above a semiconductor substrate, a first guard ring configured as a wiring stacked structure of two or more layers to adjacent to the side of the device forming region above the base wiring layer, and a second guard ring configured to be stacked with the same number of layers as the first guard ring and separated from the first guard ring, the second guard ring formed adjacent to the side of a scribe lane above the base wiring layer.

In an embodiment of the present technology, a guard ring structure of a semiconductor apparatus may include: a first guard ring configured to have a plurality of wiring stacked structures and disposed adjacent to a device forming region such that the power supplied through a power supply pad is provided to the device forming region; and a second guard ring configured to be stacked with the same number of layers as the first guard ring, to be formed adjacent to a scribe lane region, and to be formed separately from the first guard ring.

In an embodiment of the present technology, a guard ring structure of a semiconductor apparatus may include: a first guard ring configured to have a wiring stacked structure and to be located adjacent to a device forming region; a power supply pad located on the upper most portion of the wiring stacked structure; and a second guard ring configured to be stacked with the same number of layers as the first guard ring, to be formed adjacent to a scribe lane region, and to be formed separately from the first guard ring.

### BRIEF DESCRIPTION OF THE DRAWINGS

Features, aspects, and embodiments are described in conjunction with the attached drawings, in which:

FIG. 1 is a plan view of a general semiconductor wafer;

FIG. 2 is a diagram illustrating a general guard ring structure;

FIG. 3 illustrates a guard ring structure according to first embodiments of the present invention;

FIG. 4 illustrates a guard ring structure according to second embodiments of the present invention;

FIG. 5 illustrates a guard ring structure according to third embodiments of the present invention; and

FIG. 6 illustrates a guard ring structure according to fourth embodiments of the present invention.

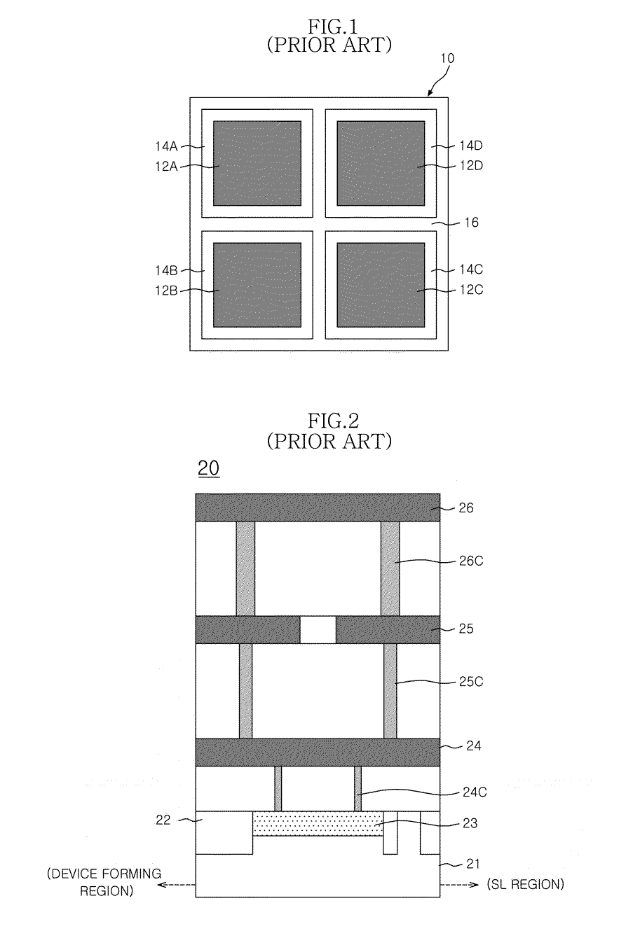

### DETAILED DESCRIPTION

Hereinafter, a semiconductor apparatus and a guard ring thereof according to the present invention will be described below with reference to the accompanying drawings through various examples of the embodiments.

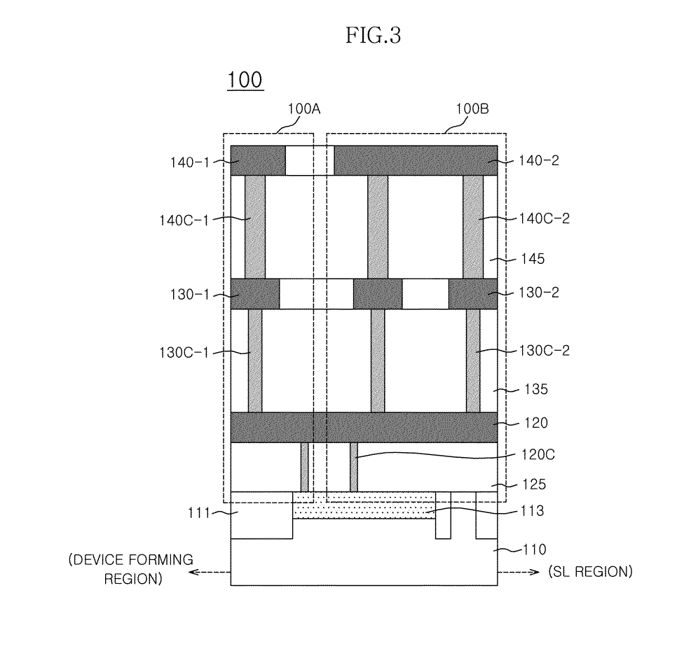

FIG. 3 illustrates a guard ring structure according to first embodiments of various embodiments of the present invention.

A guard ring structure 100 illustrated in FIG. 3 may include a semiconductor substrate 110 including an active region 113 defined by an isolation region 111, a first guard ring 100A of a two-layered to wiring stacked structure that is formed on an upper portion of the semiconductor substrate 110 and formed adjacent to a device forming region, and a second guard ring 100B of a two-layered wiring stacked structure that is formed on an upper portion of the semiconductor substrate 110 and formed adjacent to a scribe lane region SL REGION.

A first guard ring 100A and the second guard ring 100B may include a base wiring layer 120 that is electrically coupled to the active region 113 via a base contact 120C in common. The first guard ring 100A may include a first wiring layer 130-1 and a second wiring layer 140-1. The first wiring layer 130-1 may be coupled to the base wiring layer 120 via a first contact 130C-1, the second wiring layer 140-1 may be coupled to the first wiring layer 130-1 via a second contact 140C-1. The second guard ring 100B may include a first wiring layer 130-2 that is formed on the same layer or located on an equivalent layer as the first wiring layer 130-1 and separated from the first wiring layer 130-1 and a second wiring layer 140-2 that is formed on the same layer or located on an equivalent layer as the second wiring layer 140-1 and separated from the second wiring layer 140-1. The first wiring layer 130-2 may be coupled to the base wiring layer 120 via a first contact 130C-2 and the second wiring layer 140-2 may be coupled to the first wiring layer 130-2 via a second contact 140C-2.

Reference numerals 125, 135, and 145, which are not described, illustrate interlayer insulating layers.

The guard ring structure 100 illustrated in FIG. 3 may be formed separately into the first guard ring 100A of the side of the device forming region and the second guard ring 100B of the side of the scribe lane region. In the event of a dicing process, even when stress is applied to the second wiring layer 140-2 of the side of the scribe lane region, such stress may not be propagated to the first guard ring 100A. Even when the second guard ring 100B is damaged, the interfaces of the device forming region can be protected by the first guard ring 100A.

Although the first wiring layer 130-2 of the second guard ring 100B may be formed in a single pattern, it may be possible to form separately the layer in two or more patterns. When the stress applied to the upper second wiring layer 140-2 is applied to the first wiring layer 130-2, the stress may be concentrated to the pattern of the first wiring layer 130-2 of the side of the scribed lane. As such, breaking or deformation of the guard ring structure 100 may be minimized. A length of the second wiring layer 140-2 is formed to be longer than the length of the second wiring layer 140-1, and thereby the stress applied from the exterior can be more easily absorbed.

It should be understood that the guard ring structure 100 illustrated in FIG. 3 may be simultaneously formed in the event of a process of forming wiring to the device forming region. Process modification such as patterning the interlayer insulating layers 135 and 145 or patterning the wiring after it is deposited may also be performed such that the first and second guard rings 100A and 100B are formed separately.

Miniaturization and high integration of the semiconductor apparatuses is progressing and an operating speed thereof is is becoming faster. Noise such as parasitic capacitance, inductance, or resistance generated in the interior of the semiconductor circuit is increasing and a circuit design and an arrangement plan for supplying stable power to the internal circuit of the semiconductor are emerging as important issues.

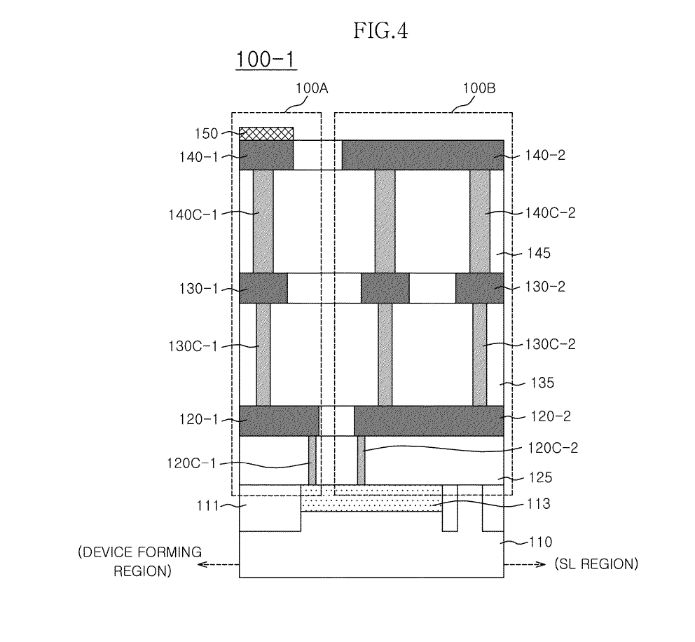

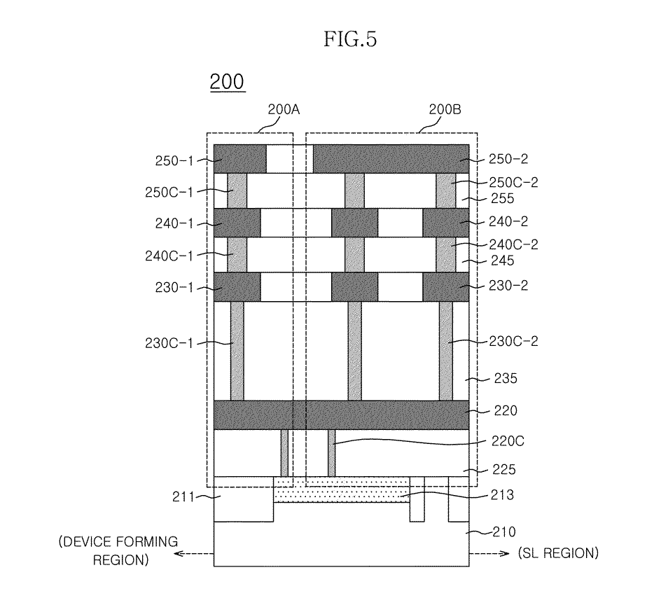

In order to compensate for the lack of power in the semiconductor chip, a measure of supplying the power through the guard ring can be derived, which will be described with reference to FIG. 4 as follows.

A guard ring structure 100-1 illustrated in FIG. 4 is similar to FIG. 3. Thus, wherever possible, the same reference numbers used throughout FIG. 3 will be used throughout FIG. 4 to refer to the same or like parts. It can been seen that the base wiring layer 120 used in common in FIG. 3 may have a separated structure such as the first base wiring layer 120-1 for the first guard ring 100A and the second base wiring layer 120-2 for the second guard ring 1008. The first base wiring layer 120-1 may be coupled to the active region 113 via a first base contact 120C-1, and the second base wiring layer 120-2 may be coupled to the active region 113 via a second base contact 120C-2. A power supply pad 150 may be formed on the upper portion of the second wiring layer 140-1 of the first guard ring 100A.

The power supplied through the power supply pad 150 can be provided to the device forming region via the first guard ring 100A. Since the base wiring layers 120-1 and 120-2 are separated from each other, the power supply to second guard ring 100B can be cut off to supply the power only to the device forming region.

FIG. 5 illustrates a guard ring structure according to third embodiments of the present invention.

A guard ring structure 200 illustrated in FIG. 5 may include a semiconductor substrate 210 including the active region 213 defined by an isolation region 211, a first guard ring 200A of a three-layered wiring stacked structure that is formed on the upper portion of the semiconductor substrate 210 and formed adjacent to the device forming region, and a second guard ring 200B of a three-layered wiring stacked structure that is formed on the upper portion of the semiconductor substrate 210 and formed adjacent to the scribe lane region SL REGION.

The first guard ring 200A and the second guard ring 200B may include a base wiring layer 220 that is electrically coupled to the active region 213 via a base contact 220C in common.

The first guard ring 200A may include a first wiring layer 230-1, a second wiring layer 240-1, and a third wiring layer 250-1. The first wiring layer 230-1 may be coupled to the base wiring layer 220 via a first contact 230C-1, the second wiring layer 240-1 may be coupled to the first wiring layer 230-1 via a second contact 240C-1, and the third wiring layer 250-1 may be electrically coupled to the second wiring layer 240-1 via a third contact 250C-1.

The second guard ring 200B may include a first wiring layer 230-2 that is formed on the same layer or located on an equivalent layer as the first wiring layer 230-1 and separated from the first wiring layer 230-1, a second wiring layer 240-2 that is formed on the same layer or located on an equivalent layer as the second wiring layer 240-1 and separated from the second wiring layer 240-1, and a third wiring layer 250-2 that is formed on the same layer or located on an equivalent layer as the third wiring layer 250-1 and separated from the third wiring layer 250-1. The first wiring layer 230-2 may be electrically coupled to the base wiring layer 220 via a first contact 230C-2, the second wiring layer 240-2 may be electrically coupled to the first wiring layer 230-2 via a second contact 240C-2, and the third wiring layer 250-2 may be electrically coupled to the second wiring layer 240-2 via a third contact 250C-2.

Reference numerals 225, 235, 245, and 255, which are not described, illustrate interlayer insulating layers.

In an embodiment of various embodiments of the present invention, although one or more of the first wiring layer 230-2 and the second wiring layer 240-2 of second guard ring 200B may be to formed in a single pattern, it may be possible to form separately the layer in two or more patterns. When the stress applied to the upper third wiring layer 250-2 or the second wiring layer 240-2 is propagated to the second wiring layer 240-2 or the first wiring layer 230-2, the stress may be concentrated to the pattern of the second wiring layer 240-2 or the pattern of the first wiring layer 230-2 of the side of the scribe lane. As such, breaking or deformation of the guard ring structure 200 may be minimized.

A length of the third wiring layer 250-2 is formed to be longer than the length of the third wiring layer 250-1, and thereby the stress applied from the exterior can be more easily absorbed.

The guard ring structure 200 illustrated in FIG. 5 has a three-layered structure. The wiring layer which is positioned at a relatively higher position functions as a buffer layer for the wiring layer which is positioned at a relatively lower position. Thereby, the stress propagating from the upper layer to the lower layer can be buffered.

It should be understood that the guard ring structure 200 illustrated in FIG. 5 may be simultaneously formed in the event of a process of forming wiring to the device forming region. Process modification such as patterning the interlayer insulating layers 235 and 245 or patterning the wiring after it is deposited may also be performed such that the first and second guard rings 200A and 200B are formed separately, and the first wiring layer 230-2 and/or the second wiring layer 240-2 that constitute the second guard ring are formed to be separated in two or more patterns.

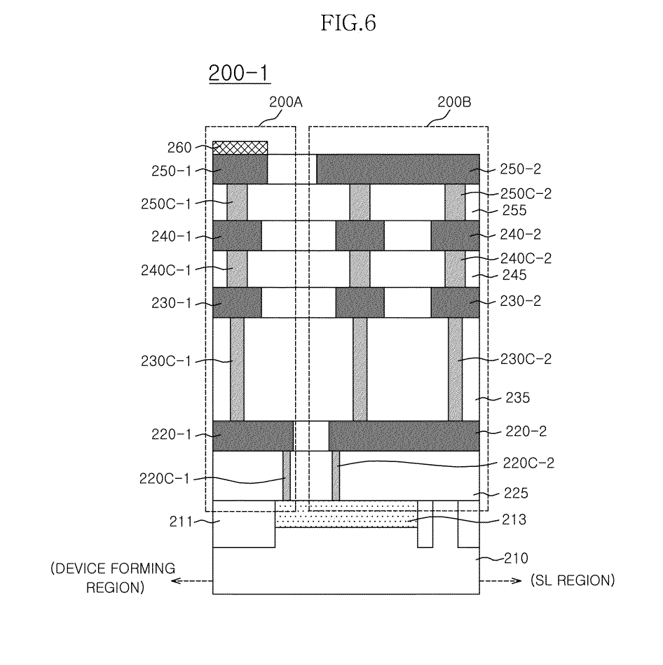

FIG. 6 illustrates a guard ring structure according to fourth embodiments of various embodiments of the present invention.

The guard ring structure 200-1 illustrated in FIG. 6 is similar to FIG. 5. Thus, wherever possible, the same reference numbers used throughout FIG. 5 will be used throughout FIG. 6 to refer to the same or like parts. It can be seen that the base wiring layer 220 that is used in common in FIG. 5 may have a separated structure such as the first base wiring layer 220-1 for the first guard ring 200A and the second base wiring layer 220-2 for the second guard ring 200B. The first base wiring layer 220-1 may be coupled to the active region 213 via a first base contact 220C-1, and the second base wiring layer 220-2 may be coupled to the active region 213 via a second base contact 220C-2. A power supply pad 260 may be formed on the upper portion of the third wiring layer 250-1 of the first guard ring 200A.

The power supplied through the power supply pad 260 may provided to the device forming region through the first guard ring 200A. As such, the power required to operate the devices of the device forming region can be supplemented to the devices.

It should be understood by those skilled in the art that the present invention may be made in other specific forms therein without departing from the technical spirit and essential characteristics of the present invention. It must be understood that the aforementioned embodiments are examples of embodiments in all aspects and are not limited to such embodiments. The scope of the present invention is limited only by the scope of the appended claims to be described below rather than a detailed description. It should be is construed that various modifications or modified forms derived from the meaning, the scope and the equivalents of the appended claims are within the present invention.

While various embodiments have been described above, it will be understood to those skilled in the art that the embodiments described are by way of example only. Accordingly, the semiconductor apparatus and the guard ring thereof described herein should not be limited based on the described embodiments. Rather, the semiconductor apparatus described herein should only be limited in light of the claims that follow when taken in conjunction with the above description and accompanying drawings.

What is claimed is:

1. A guard ring structure of a semiconductor apparatus formed at an edge of a device forming region, the guard ring structure comprising:
a base wiring layer located above a semiconductor substrate;
a first guard ring configured as a wiring stacked structure of two or more layers adjacent to the side of the device forming region above the base wiring layer; and
to a second guard ring configured to be stacked with the same number of layers as the first guard ring and separated from the first guard ring, the second guard ring formed adjacent to the side of a scribe lane above the base wiring layer.

2. The structure according to claim 1, wherein the first guard ring includes a first wiring layer formed above the base wiring layer; and
a second wiring layer of the first guard ring formed above the first wiring layer of the first guard ring, and
wherein the second guard ring includes a first wiring layer formed on the same layer as the first wiring layer of the first guard ring, the first wiring layer of the second guard ring separated from the first wiring layer of the first guard ring, and the first wiring layer of the second guard ring includes one or more wiring patterns; and
a second wiring layer of the second guard ring formed on the same layer as the second wiring layer of the first guard ring and the second wiring layer of the second guard ring separated from the second wiring layer of the first guard ring.

3. The structure according to claim 2, wherein the length of the second wiring layer of the second guard ring is longer than the length of the second wiring layer of the first guard ring.

4. The structure according to claim 1, wherein the semiconductor substrate includes an active region defined by an isolation region, and
the base wiring layer is formed above a base contact electrically coupled to the active region.

5. The structure according to claim 1, wherein the base wiring layer includes a first base wiring layer formed adjacent to the side of the device forming region; and
a second base wiring layer configured to be formed adjacent to the side of the scribe lane and formed to be separated from the first base wiring layer,
wherein the first guard ring is located above and includes the first base wiring layer and the first guard ring includes a power supply pad formed on the uppermost wiring layer, and the second guard ring is located above and includes the second base wiring layer.

6. The structure according to claim 5, wherein the semiconductor substrate includes an active region defined by an isolation region, and
wherein the first base wiring layer is formed above a first base contact electrically coupled to the active region, and the second base wiring layer is formed above a second base contact electrically coupled to the active region.

7. The structure according to claim 1, wherein the first guard ring includes a first wiring layer formed above the base wiring layer;
a second wiring layer formed above the first wiring layer of the first guard ring; and
a third wiring layer formed above the second wiring layer of the first guard ring, and
wherein the second guard ring includes a first wiring layer configured to be formed on the same layer as the first wiring layer of the first guard ring, the first wiring layer of the second guard ring separated from the first wiring layer of the first guard ring and the first wiring layer of the second guard ring includes one or more wiring patterns;
a second wiring layer of the second guard ring formed on the same layer as the second wiring layer of the first guard ring, the second wiring layer of the second guard ring separated from the second wiring layer of the first guard ring and the second wiring layer of the second guard ring includes one or more wiring patterns; and
a third wiring layer of the second guard ring formed on the same layer as the third wiring layer of the first guard ring.

8. The structure according to claim 7, wherein the length of the third wiring layer of the second guard ring is longer than the length of the third wiring layer of the first guard ring.

9. The structure according to claim 7, wherein the base wiring layer includes a first base wiring layer formed adjacent to the side of the device forming region; and
a second base wiring layer formed adjacent to the side of the scribe lane and separated from the first base wiring layer, and
wherein the first guard ring is located above and includes the first base wiring layer and the first guard ring includes a power supply pad formed on the third wiring layer of the first guard ring, and the second guard ring is located above and includes the second base wiring layer.

10. The structure according to claim 9, wherein the semiconductor substrate includes an active region defined by an isolation region, and
wherein the first base wiring layer is formed above a first base contact electrically coupled to the active region, and the second base wiring layer is formed above a second base contact electrically coupled to the active region.

11. A guard ring structure of a semiconductor apparatus comprising:
a first guard ring configured to have a plurality of wiring stacked structures and to be disposed adjacent to a device forming region such that the power supplied through a power supply pad is provided to the device forming region; and
a second guard ring configured to be stacked with the same number of layers as the first guard ring, to be formed adjacent to a scribe lane region, and to be formed separately from the first guard ring.

12. The structure according to claim 11, wherein the first guard ring includes a first base wiring layer electrically coupled to an active region of a semiconductor substrate;
a first wiring layer of the first guard ring formed above the first base wiring layer;
a second wiring layer of the first guard ring formed above the first wiring layer of the first guard ring; and
the power supply pad located on the second wiring layer of the first guard ring, and
wherein the second guard ring includes a second base wiring layer electrically coupled to the active region;
a first wiring layer of the second guard ring formed on the same layer as the first wiring layer of the first guard ring, the first wiring layer of the second guard ring formed separately from the first wiring layer of the first guard ring, and first wiring layer of the second guard ring includes one or more wiring patterns; and
a second wiring layer of the second guard ring formed on the same layer as the second wiring layer of the first guard ring and the second wiring layer of the second guard ring formed separately from the second wiring layer of the first guard ring.

13. The structure according to claim 12, wherein the length of the second wiring layer of the second guard ring is longer than the length of the second wiring layer of the first guard ring.

14. The structure according to claim 11, wherein the first guard ring includes a first base wiring layer electrically coupled to an active region of a semiconductor substrate;
a first wiring layer of the first guard ring located above the first base wiring layer;
a second wiring layer of the first guard ring located above the first wiring layer of the first guard ring;
a third wiring layer of the first guard ring located above the second wiring layer of the first guard ring; and
the power supply pad formed on the third wiring layer of the first guard ring, and
wherein the second guard ring includes a second base wiring layer electrically coupled to the active region;
a first wiring layer of the second guard ring formed on the same layer as the first wiring layer of the first guard ring, the first wiring layer of the second guard ring formed separately from the first wiring layer of the first guard ring, and the first wiring layer of the second guard ring includes one or more wiring patterns;
a second wiring layer of the second guard ring formed on the same layer as the second wiring layer of the first guard ring, the second wiring layer of the second guard ring formed separately from the second wiring layer of the first guard ring, and the second wiring layer of the second guard ring includes one or more wiring patterns; and
a third wiring layer of the second guard ring formed on the same layer as the third wiring layer of the first guard ring.

15. The structure according to claim 14, wherein the length of the third wiring layer of the second guard ring is longer than the length of the third wiring layer of the first guard ring.

16. A guard ring structure of a semiconductor apparatus comprising:
a first guard ring configured to have a wiring stacked structure and to be located adjacent to a device forming region;
a power supply pad located on the upper most portion of the wiring stacked structure; and
a second guard ring configured to be stacked with the same number of layers as the first guard ring, to be formed adjacent to a scribe lane region, and to be formed separately from the first guard ring.

17. The structure according to claim 16, wherein:
the layers of the second guard ring are electrically coupled to each other by contacts located between the layers of the second guard ring; and
the layers of the first guard ring are electrically coupled to each other by contacts located between the layers of the first guard ring.
